(19) United States
(12) Patent Application Publication
(10) Pub. No.: US 2024/0332279 A1
(43) Pub. Date: Oct. 3, 2024

(54) DEVICE HAVING RP CELL REGION INCLUDING L-SHAPE AND RESIDENT REGIONS AND METHOD OF MANUFACTURING SAME

(71) Applicant: TAIWAN SEMICONDUCTOR MANUFACTURING COMPANY, LTD., Hsinchu (TW)

(72) Inventors: Chun-Hsuan WANG, Hsinchu (TW); Wei-Cheng LIN, Hsinchu (TW); Jiann-Tyng TZENG, Hsinchu (TW)

(21) Appl. No.: 18/403,656

(22) Filed: Jan. 3, 2024

Related U.S. Application Data
(60) Provisional application No. 63/492,399, filed on Mar. 27, 2023.

(51) Int. Cl. H01L 27/02

(52) U.S. Cl. CPC H01L 27/0207

(57) ABSTRACT

A rectangular parallelepiped (RP) cell region includes: a 3D L-shape region, a dummy region and a resident region each of which includes transistor components, transistors of the resident region being free from comprising a function of the L-shape region; the dummy region and the resident region being in first notch formed by an arm and a stem of the L-shape region; first type transistors of the arm being stacked correspondingly over second type transistors of the first part of the stem; dummy transistor(s) of the dummy region being stacked over second type transistors of the second part of the stem; and first type transistors of the resident region being stacked over second type transistors of the third part of the stem.

### PRIORITY

The present application claims the priority of U.S. Provisional Application No. 63/492,399, filed Mar. 27, 2023, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a three-quarter perspective diagram of a complementary field-effect transistor (CFET) stack, in accordance with some embodiments.

FIG. 2 is a cross-section of a rectangular parallelepiped (RP) cell region, in accordance with some embodiments.

FIG. 3A is a side view of an RP cell region, in accordance with some embodiments.

FIG. 3B-3D are three-quarter perspective views of corresponding RP cell regions, in accordance with some embodiments.

FIG. 3E-3G are three-quarter perspective views of corresponding RP cell regions being abutted to each other, in accordance with some embodiments.

FIGS. 4A-4H are layout diagrams of corresponding arrangements of active regions, in accordance with some embodiments.

FIGS. 5A-5D are layout diagrams of cell regions, in accordance with some embodiments.

FIGS. 6A-6C are partial layout diagrams of cell regions, in accordance with some embodiments.

FIGS. 6D-6I are layout diagrams of cell regions, in accordance with some embodiments.

FIGS. 7A-7B are flowcharts of corresponding methods of manufacturing a memory device, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a device includes a first rectangular parallelepiped (RP) cell region. The RP cell region includes groups of transistor components arranged in stacks according to a complementary field-effect transistor (CFET) architecture, where each group of transistor components represents a transistor. The first RP cell region includes a three-dimensional (3D) L-shape region, a dummy region and a resident region. The dummy region and the resident region are in a first notch of the L-shape region. The active transistors of the L-shape region have corresponding operabilities which comprise a function of the L-shape region that represents a function of the RP cell region. The dummy region includes one or more dummy transistors. The resident region includes one or more active transistors having corresponding operabilities which are free from comprising the function of the L-shape region. According to another approach, the notch of an L-shape region of an RP cell region was filled only with a dummy region. Relative to a first direction (e.g., parallel to the X-axis), the dummy region according to other approach is wider than the dummy region according to present embodiments. The larger dummy region according to the other approach wastes space.

An advantage of present embodiments of an RP cell region (which have an L-shape region whose first notch is filled with a dummy region and a resident region) is less wasted space as compared to the other approach because the dummy region of present embodiments is narrower than the dummy region according to the other approach. As such, a density of present embodiments of a device which includes the RP cell region which has an L-shape region whose first notch is filled with a dummy region and a resident region is greater than a density of a device which includes the RP cell region according to the other approach. An advantage of present embodiments of such a device (which includes the RP cell region which has an L-shape region whose first notch is filled with a dummy region and a resident region) is that inclusion of the resident region facilitates not only abutting but overlapping first and second instances of the RP cell region, where the second instance of the RP cell region is a complementarily oriented relative to the first instance of the RP cell region. In such present embodiments, abutting and overlapping of such RP cell regions (which have an L-shape region whose first notch is filled with a dummy region and a resident region) facilitates greater device densities as compared to the other approach.

In the first RP cell region, the L-shape region includes a stem and an arm. The stem extends in a first direction (e.g., parallel to the X-axis) and includes first, second and third parts. The arm extends from the first part of the stem in a second direction (e.g., parallel to the Z-axis) perpendicular to the first direction (X-axis) to form the first notch. Each of the arm and the resident region correspondingly includes one or more first type ones of the active transistors (first active transistors) (e.g., NFETs). The stem includes second type ones of the active transistors (second active transistors) (e.g., PFETs) configured with a second dopant type (e.g., P-type) different than the first dopant type. According to the CFET architecture, and relative to a third direction (e.g., parallel to the Z-axis): the one or more first type active transistors (e.g., NFETs) of the arm are stacked correspondingly with respect to one or more of the second active transistors (e.g., P-type) of the first part of the stem; the one or more dummy transistors of the dummy region are stacked correspondingly with respect to one or more of the second type active transistors (e.g., PFETs) of the second part of the stem, and the one or more first type active transistors (e.g., NFETs) of the resident region are stacked correspondingly with respect to one or more of the second type active transistors (PFETs) of the third part of the stem. When first and second instances of the RP cell region are not only abutted but overlapped, the one or more first type active transistors (e.g., NFETs) of each resident region are stacked correspondingly with respect to one or more of the second type active transistors (PFETs) of the third part of the corresponding stem.

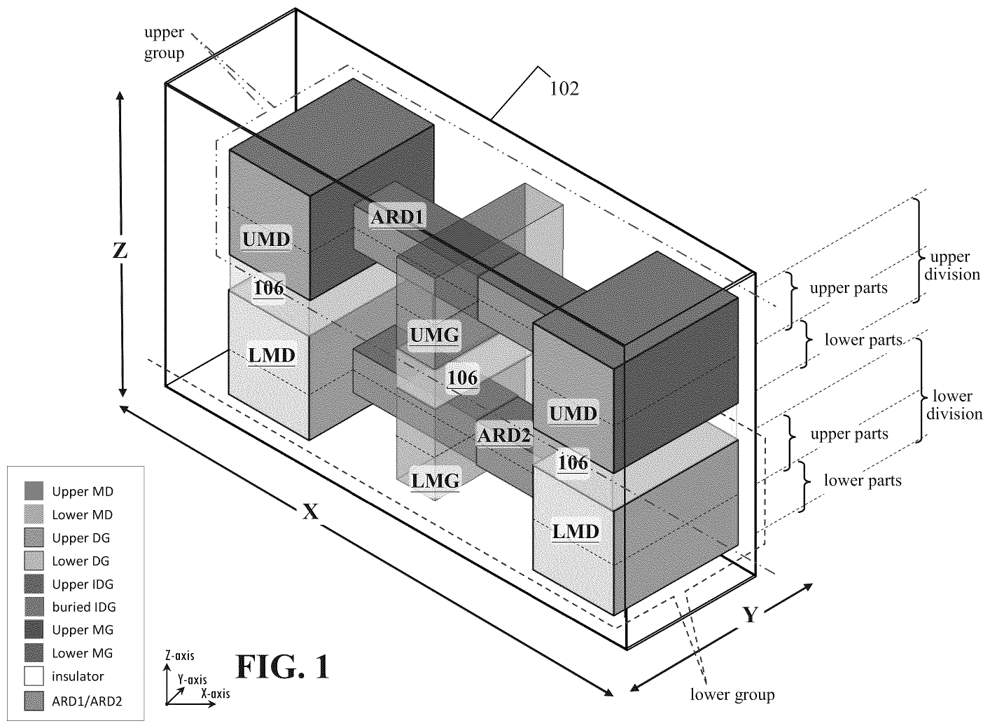

FIG. 1 is a three-quarter perspective diagram of a complementary field-effect transistor (CFET) stack 102, in accordance with some embodiments.

CFET stack 102 is includes an upper group of transistor components stacked on a lower group of transistor components. The upper group of transistors components represent a first type of metal-oxide field-effect (MOSFET) transistor which uses a first type of doping, e.g., negative type (N-type) doping, and is referred to as a first-type-channel MOSFET, e.g., a negative-channel MOSFET (NFET) or as an NMOS transistor. The lower group of transistors components represent a second type of MOSFET transistor which uses a second type of doping, e.g., positive type (P-type) doping, and is referred to as a second-type-channel MOSFET, e.g., a positive-channel MOSFET (PFET) or as a PMOS transistor. In some embodiments, the first type of doping is P-type and the second type of doping is N-type. In some embodiments, when CFET stack 102 is included as one of multiple CFET stacks in a CFET-based device, the upper group of transistors components is described as being included in an upper division of the CFET-based device, and the lower group of transistors is described as being included in the lower division of the CFET-based device.

In FIG. 1, first, second and third orthogonal directions are assumed that are, e.g., correspondingly parallel to the X-axis, Z-axis and Y-axis.

The upper group includes an active region ARD1 having the first type of dopant that extends parallel to the X-axis. First and second instances of an upper metal-to-source/drain (MD) contact UMD are formed correspondingly around first and second ends of active region ARD1. An upper metal-to-gate (MG) contact UMG is formed around a central region of active region ARD1 such that the upper MG contact UMG is between the first and second instances of upper MD contact UMD.

The lower group includes an active region ARD2 having the second type of dopant that extends parallel to the X-axis. First and second instances of a lower MD contact LMD are formed correspondingly around first and second ends of active region ARD2. A lower MG contact LMG is formed around a central region of active region ARD2 such that the lower MG contact LMG is between the first and second instances of the lower MD contact LMD. In some embodiments, the lower active region has the first type dopant and the upper active region has the second type dopant.

In FIG. 1, relative to the Z-axis: the active region ARD1 is aligned over the active region ARD2; the first and second instances of the upper MD contact UMD are aligned correspondingly over the first and second instances of the lower MD contact MD; and the upper MG contact UMG is aligned over the lower MG contact UMG. Relative to the Z-axis, each of the upper MG contact UMG, the lower MG contact UMG, the first and second instances of the upper MD contact UMD, and the first and second instances of the lower MD contact MD correspondingly has upper and lower parts.

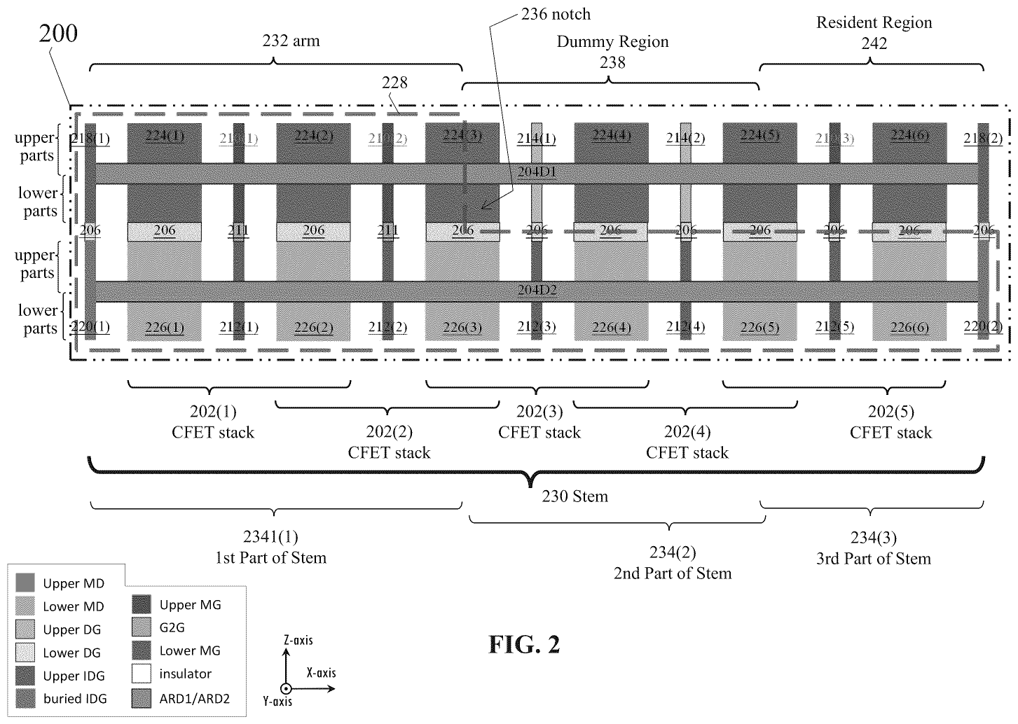

In FIG. 1, an instance of an insulator 106 is formed between each of the following: the upper MG contact UMG and the lower MG contact UMG; the first instances of the upper MD contact UMD and the lower MD contact LMD; and the second instances of the upper MD contact UMD and the lower MD contact LMD. In some embodiments, the instance of insulator 106 between the upper MG contact UMG and the lower MG contact UMG is replaced with an MG-to-MG (G2G) contact (211 FIG. 2). In some embodiments, the instance of insulator 106 between the first instances of the upper MD contact UMD and the lower MD contact LMD is replaced with an MD-to-MD (D2D) contact (not shown). In some embodiments, the instance of insulator 106 between the second instances of the upper MD contact UMD and the lower MD contact LMD is replaced with a D2D contact (not shown).

FIG. 2 is a cross-section of a rectangular parallelepiped (RP) cell region 200, in accordance with some embodiments.

In FIG. 2, first, second and third orthogonal directions are assumed that are, e.g., correspondingly parallel to the X-axis, Z-axis and Y-axis.

RP cell region 200 includes groups of transistor components arranged in stacks 202(1)-202(5) according to the CFET architecture (CFET stacks), where each group of transistor components represents a transistor. RP cell region also includes an L-shape region 228, a dummy region 238 and a resident region 242. Dummy region 238 and resident region 242 are in a first notch 236 of L-shape region 228. An L-shape region, e.g., L-shape region 228, has a shape resembling a three-dimensional uppercase letter L.

Active transistors are represented by the groups of transistor components in L-shape region 228 and resident region 242. The active transistors represented by the groups of transistor components in L-shape region 228 have corresponding operabilities which comprise a function of L-shape region 228. The function of L-shape region 228 represents a function of RP cell region 200.

In FIG. 2, one or more active transistors represented by the one or more groups of transistor components in resident region 242 have corresponding operabilities which are free from comprising the function of L-shape region 228. Rather, the operabilities of the one or more active transistors of resident region 242 comprise a function of another cell region, e.g., a function of another L-shape region (e.g., 328(2)) of another RP cell region (e.g., 300(2)) where the function of the other L-shape region (e.g., 328(2)) represents the function of the other RP cell region (e.g., 300(2)). One or more groups of transistor components in dummy region 238 correspondingly represent one or more dummy transistors.

In RP cell region 200, L-shape region 228 includes a stem 230 and an arm 232. Stem 230 extends parallel to the X-axis and includes a first part 234(1), a second part 234(2) and a third part 234(3). Arm 232 extends from first part 234(1) of stem 230 along the Z-axis to form first notch 236.

Each of arm 232 and resident region 242 correspondingly includes one or more first ones of the active transistors having the first type of dopant (first active transistors) (e.g., NFETs). Stem 230 includes second ones of the active transistors having the second type of dopant (second active transistors) (e.g., PFETs).

RP cell region 200 includes: an active region 204D1 having a first type of dopant (e.g., N-type) over an active region 204D2 having a second type of dopant (e.g., P-type); lower MG contacts 212(1)-212(5); upper MG contacts 210(1)-210(3) over corresponding lower MG contacts 212(1), 212(2) and 212(5); upper DG contacts 214(1)-214(2) over corresponding lower MG contacts 212(1)-212(2); upper MD contacts 224(1)-224(6) over corresponding lower MD contacts 226(1)-226(6); instances of an MG-to-MG (G2G) contact 211 between upper MG contacts 210(1)-210(2) and corresponding lower MG contacts 212(1)-212(2); and instances of an insulator 206 between (A) upper MG contact 210(3) and lower MG contact 212(5), (B) upper DG contacts 214(1)-214(2) and corresponding lower MG contacts 212(3)-213(4), and (C) upper MD contacts 224(1)-224(6) and corresponding lower MD contacts 226(1)-226(6).

In FIG. 2, examples of the upper groups include: upper MG contact 210(1), upper MD contacts 224(1)-224(2) and a corresponding portion of active region 204D1 which represent a first instance of the first active transistor (e.g., a first NFET) and is included in each of CFET stack 202(1) and arm 232 of L-shape region 228; upper MG contact 210(2), upper MD contacts 224(2)-224(3) and a corresponding portion of active region 204D1 which represent a second instance of the first active transistor (e.g., a second NFET) and is included in each of CFET stack 202(2) and arm 232 of L-shape region 228; upper MG contact 210(3), upper MD contacts 224(5)-224(6) and a corresponding portion of active region 204D1 which represent a third instance of the first active transistor (e.g., a third NFET) and is included in each of CFET stack 202(5) and resident region 242; upper DG contact 214(1), upper MD contacts 224(3)-224(4) and a corresponding portion of active region 204D1 which represent a first dummy transistor and is included in each of CFET stack 202(3) and dummy region 238; and upper DG contact 214(2), upper MD contacts 224(4)-224(5) and a corresponding portion of active region 204D1 which represent a second dummy transistor and is included in each of CFET stack 202(4) and dummy region 238.

In FIG. 2, examples of the lower groups include: lower MG contact 212(1), lower MD contacts 226(1)-226(2) and a corresponding portion of active region 204D2 which represent a first instance of the second active transistor having the second type of dopant (e.g., a first PFET) and is included in each of CFET stack 202(1) and stem 230 of L-shape region 228; lower MG contact 212(2), lower MD contacts 226(2)-226(3) and a corresponding portion of active region 204D2 which represent a second instance of the second active transistor (e.g., a second PFET) and is included in each of CFET stack 202(2) and stem 230 of L-shape region 228; lower MG contact 212(3), lower MD contacts 226(3)-226(4) and a corresponding portion of active region 204D2 which represent a third instance of the second active transistor (e.g., a third PFET) and is included in each of CFET stack 202(3) and stem 230 of L-shape region 228; lower MG contact 212(4), lower MD contacts 226(4)-226(5) and a corresponding portion of active region 204D2 which represent a fourth instance of the second active transistor (e.g., a fourth PFET) and is included in each of CFET stack 202(4) and stem 230 of L-shape region 228; and lower MG contact 212(5), lower MD contacts 226(5)-226(6) and a corresponding portion of active region 204D2 which represent a fifth instance of the second active transistor (e.g., a fifth PFET) and is included in each of CFET stack 202(5) and stem 230 of L-shape region 228. In some embodiments, lower active region 204D2 has the first type of dopant and upper active region 204D1 has the second type of dopant.

RP cell region 200 further includes: upper isolation dummy gates (IDGs) 218(1)-218(2) over corresponding lower IDGs 220(1)-220(2); and instances of an insulator 206 between upper IDGs 218(1)-218(2) and corresponding lower IDGs 220(1)-220(2). In some embodiments, an upper IDG is aligned over a lower MG contact. In some embodiments, a lower IDG is aligned under an upper MG contact.

In some embodiments, an isolation dummy gate (e.g., each of upper IDGs 218(1)-218(2) and lower IDGs 220(1)-220(2)) is a dielectric structure that includes one or more dielectric materials and functions as an electrical isolation structure. Accordingly, an isolation dummy gate is not a structure that is electrically conductive and thus does not function, e.g., as an active gate of a transistor. An isolation dummy gate includes one or more dielectric materials and functions as an electrical isolation structure. In some embodiments, an isolation dummy gate is based on a gate structure as a precursor. In some embodiments, a dummy gate structure includes a gate conductor, a gate-insulator layer, (optionally) one or more spacers, or the like. In some embodiments, an isolation dummy gate is formed by first forming an upper MG contact or a lower MG contact, sacrificing/removing (e.g., etching) the upper or lower MG contact to form a trench, (optionally) removing a portion of an active region (e.g., active region 204D1 or 204D2) that was formerly surrounded by the corresponding the upper or lower MG contact to deepen the trench, and then filling the trench with one or more dielectric materials such that the physical dimensions of the resultant electrical isolation structure, i.e., the upper or lower IDG, are similar to the dimensions of the upper or lower MG contact which was sacrificed. In some embodiments, an upper or lower IDG is a dielectric feature that includes one or more dielectric materials (e.g., oxide, nitride, oxynitride, or other suitable materials), and functions as an isolation feature. In some embodiments, an upper or lower IDG is a continuous polysilicon on oxide diffusion (OD) edge structure, and is referred to as an upper or lower CPODE structure.

In FIG. 2, relative to the X-axis: upper IDG 218(1), lower IDG 220(1) and the corresponding instance of insulator 206 represent a left boundary of RP cell region 200; and upper IDG 218(2), lower IDG 220(2) and the corresponding instance of insulator 206 represent a right boundary of cell region RP 200.

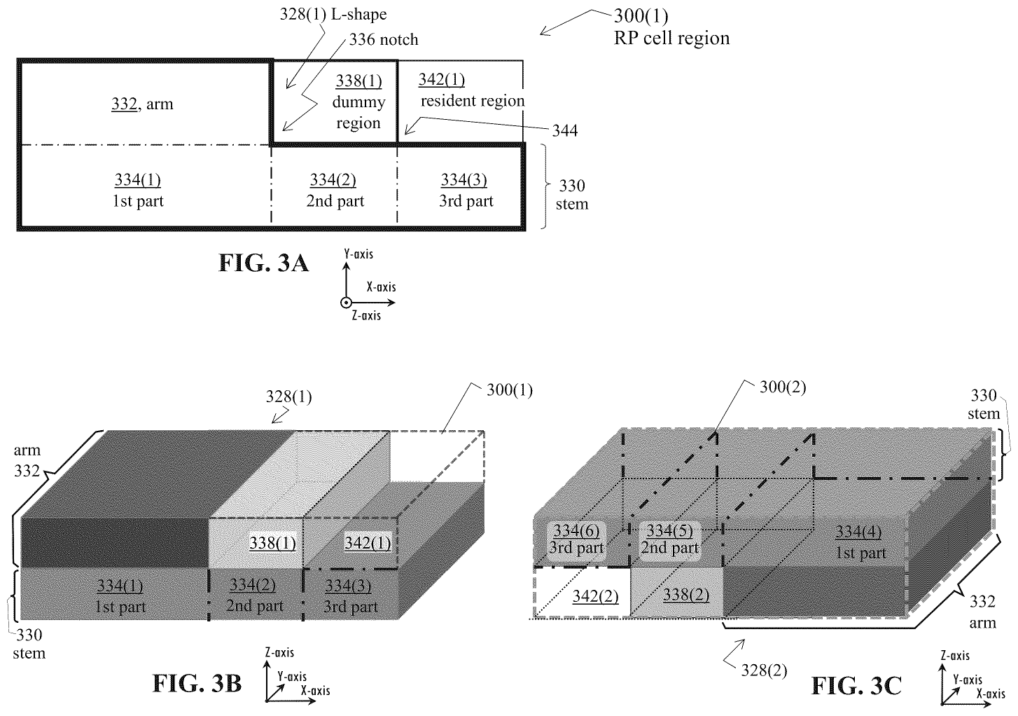

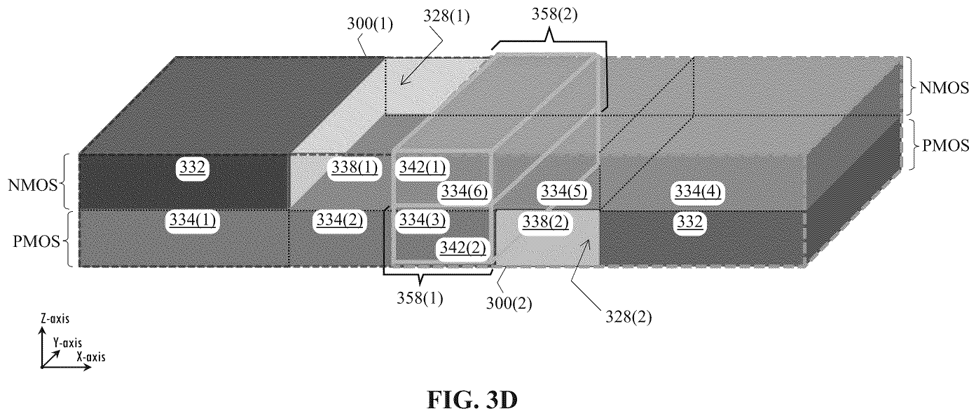

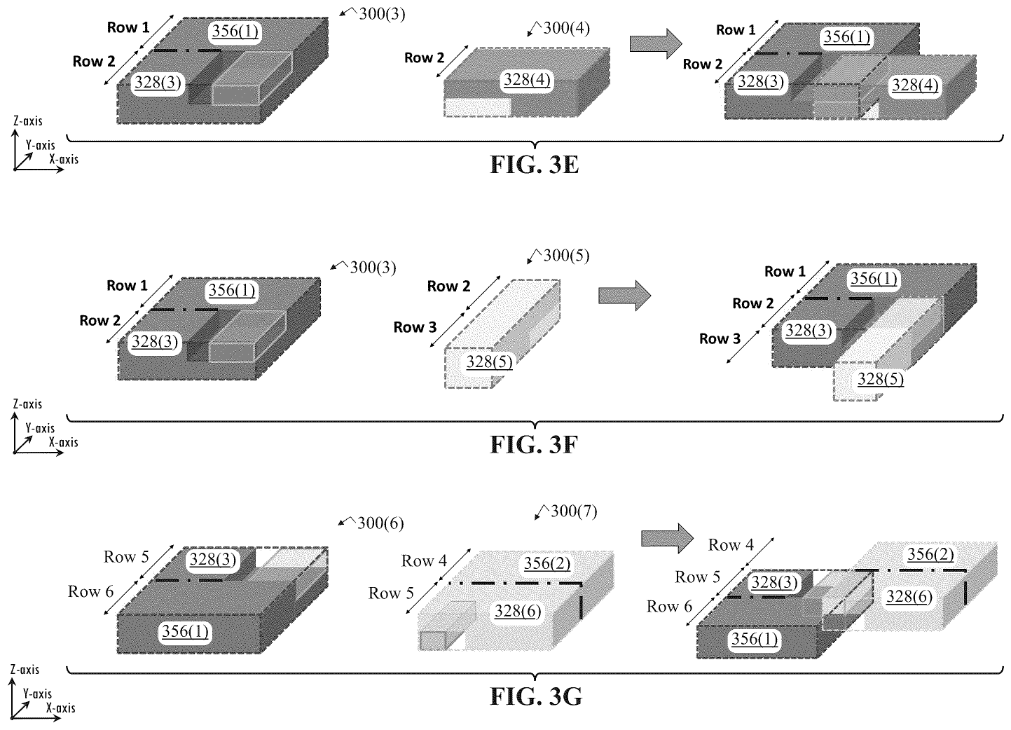

FIGS. 3A-3B correspondingly are a side view and three-quarter perspective view of an RP cell region 300(1), in accordance with some embodiments.

In FIGS. 3A-3C, and in FIGS. 3C-3G as well, first, second and third orthogonal directions are assumed that are, e.g., correspondingly parallel to the X-axis, Z-axis and Y-axis.

In FIGS. 3A-3B, RP cell region 300(1) includes an L-shape region 328(1), a dummy region 338(1) and a resident region 342(1). L-shape region 328(1) includes a stem 330 and an arm 332. Stem extends parallel to the X-axis and includes a first part 334(1), a second part 334(2) and a third part 334(3). Arm 332 extends from first part 334(1) of stem 330 along the Z-axis to form first notch 336.

In FIGS. 3A-3B, dummy region 338(1) and resident region 342(1) are in first notch 336. Relative to the X-axis, dummy region 338(1) is between arm 332 and resident region 342(1). Arm 332 is aligned over first part 334(1) of stem 330. Dummy region 33(1) is aligned over second part 334(2) of stem 330. Resident region 342(1) is aligned over third part 334(3) of stem 330. Dummy region 33(1) and second (334(2) and third (334(3) parts of stem 330 form a second notch 344. Resident region 342(1) is in second notch 344.

FIG. 3C is a three-quarter perspective view of an RP cell region 300(2), in accordance with some embodiments.

RP cell region 300(2) is complementarily oriented relative to RP cell region 300(1). Relative to each of the X-axis and the Y-axis, RP cell region 300(2) is rotated 180 degrees relative to RP cell region 300(1).

In FIG. 3C, RP cell region 300(2) includes an L-shape region 328(2), a dummy region 338(2) and a resident region 342(2). L-shape region 328(2) includes a stem 330 and an arm 332. Stem extends parallel to the X-axis and includes a first part 334(4), a second part 334(5) and a third part 334(6). Arm 332 extends from first part 334(4) of stem 330 along the Z-axis to form first notch 336 (not called out in FIG. 3C).

In FIG. 3C, dummy region 338(2) and resident region 342(2) are in first notch 336 (not called out in FIG. 3C). Relative to the X-axis, dummy region 338(2) is between arm 332 and resident region 342(2). Arm 332 is aligned under first part 334(2) of stem 330. Dummy region 33(2) is aligned under second part 334(2) of stem 330. Resident region 342(2) is aligned under third part 334(3) of stem 330. Dummy region 33(2) and second (334(2) and third (334(3) parts of stem 330 form a second notch 344 (not called out in FIG. 3C). Resident region 342(2) is in second notch 344.

FIG. 3D is a three-quarter perspective view of RP cell regions 300(1) and 300(2), in accordance with some embodiments.

In FIG. 3D, relative to the X-axis, RP cell region 300(2) is abutted to RP cell region 300(1). Moreover, a portion of RP cell region 300(2) overlaps a portion of RP cell region 300(1). The overlapped portion of RP cell region 300(1) includes third part 334(3) and resident region 342(1). The overlapped portion of RP cell region 300(2) includes third part 342(6) and resident region 342(2).

In FIG. 3D, in effect: third part 334(6) of RP cell region 300(2) represents resident region 342(1) of RP cell region 300(1); and third part 342(3) of RP cell region 300(1) represents resident region 342(2) of RP cell region 300(2).

In some embodiments, RP cell region 300(1) is described as including a first U-shaped region of active transistors that includes L-shape region 328(1) and resident region 342(1), and where dummy region 338(1) is in a gap of the first U-shaped region. In some embodiments, RP cell region 300(2) is described as including a second U-shaped region of active transistors that includes L-shape region 328(2) and resident region 342(2), and where dummy region 338(2) is in a gap of the second U-shaped region. A U-shape region has a shape resembling a three-dimensional uppercase letter U. In some embodiments, an uppercase letter U includes first and second stems extending parallel from corresponding first and second ends of a shared arm (or base), with a gap between the first and second stems. In some embodiments, the shared arm (or base) is arcuate. In some embodiments, the arcuate shared arm (or base) is referred to as a shared arch.

RP cell regions 300(1) and 300(2) share third part 334(3) of RP cell region 300(1) and third part 334(6) of RP cell region 300(2). As third part 334(6) of RP cell region 300(2) is stacked over third part 334(3) of RP cell region 300(1), third part 334(6) of RP cell region 300(2) and third part 334(3) of RP cell region 300(1) represent a CFET stack which is shared by RP cell regions 300(1) and 300(2).

According to the other approach, each of third part 334(3) of RP cell region 300(1) and third part 334(6) of RP cell region 300(2) would be counterpart dummy regions in counterpart first and second RP cell regions. The counterpart dummy regions according to the other approach are comprised of one or more groups of transistor components that correspondingly represent one or more dummy transistors. The counterpart dummy regions according to the other approach waste space. By contrast, the CFET stack represented by third part 334(3) of RP cell region 300(1) and third part 334(6) of RP cell region 300(2) correspondingly represents recovered, i.e., unwasted, regions 358(1) and 358(2) as compared to the other approach. As such, a density of present embodiments of a device which includes RP cell regions 300(1)-300(2) rather than the counterpart first and second RP cell regions according to the other approach has a higher density than a device which includes the counterpart first and second RP cell regions according to the other approach.

FIG. 3E-3G are three-quarter perspective views of corresponding cell regions being abutted to each other, in accordance with some embodiments.

At the left side, each of FIGS. 3E-3F includes an RP cell region 300(3). FIG. 3G includes an RP cell region 300(6) which is version of RP cell region 300(3). Relative to a plane formed by the X-axis and the Z-axis, RP cell region 300(6) of FIG. 3G is mirror symmetric with respect to RP cell region 300(3) of FIGS. 3E-3F. Each of RP cell regions 300(3) and 300(6) includes: an L-shape region 328(3) and an internal RP region 3561(1). Relative to the Y-axis, internal RP region 3561(1) is abutted to L-shape regions 328(3).

FIGS. 3E-3F are arranged into rows 1 and 2 that extend parallel to the X-axis. Regarding RP cell region 300(3), internal RP region 356(1) is in row 1 and L-shape region 328(3) is in row 2.

In the middle, FIG. 3E further includes an RP cell region 300(4), the latter including an L-shape region 328(4). Relative to each of the X-axis and the Y-axis, RP cell region 300(2) is rotated 180 degrees relative to RP cell region 300(1).RP cell region 300(4) is in row 2. Relative to each of the X-axis and the Y-axis, RP cell region 300(4) is rotated 180 degrees relative to RP cell region 300(3).

At the right side of FIG. 3E, and relative to row 2, a space-recovering arrangement is shown in which L-shape region 328(4) of RP cell region 300(4) not only abuts but also partially overlaps L-shape region 328(3) of RP cell region 300(3).

Regarding FIG. 3F, the middle of FIG. 3F further includes an RP cell region 300(5), the latter including an L-shape region 328(5). Relative to the X-axis, L-shape region 328(5) of RP cell region 300(5) is rotated 180 degrees relative to L-shape region 328(3) of RP cell region 300(3). Relative to the Z-axis, RP cell region 300(5) is rotated 90 degrees counterclockwise relative to RP cell region 300(3).

FIG. 3F is further arranged to include a row 3 that extends parallel to the X-axis. RP cell region 300(5) spans rows 2 and 3.

At the right side of FIG. 3F, and relative to row 2, a space-recovering arrangement is shown in which L-shape region 328(5) of RP cell region 300(5) not only abuts but also partially overlaps L-shape region 328(3) of RP cell region 300(3).

Regarding FIG. 3G, the middle of FIG. 3G further includes an RP cell region 300(7), the latter including an L-shape region 328(6) and in internal RP region 356(2). RP cell region 300(7) is complementarily oriented with respect to RP cell region 300(6) as follows: relative to each of the X-axis and the Y-axis, an intermediary RP cell region (not shown) is rotated 180 degrees relative to RP cell region 300(6); and relative to a plane formed the X-axis and the Y-axis, RP cell region 300(7) is mirror symmetric with respect to the intermediary RP cell region (not shown).

FIG. 3F is further organized to include rows 4, 5 and 6 that extend parallel to the X-axis. Regarding RP cell region 300(6), L-shape region 328(3) is in row 5 and internal RP region 356(1) is in row 6. Regarding RP cell region 300(7), internal RP region 356(2) is in row 4 and L-shape region 328(6) is in row 5.

At the right side of FIG. 3G, and relative to row 6, a space-recovering arrangement is shown in which L-shape region 328(6) of RP cell region 300(7) not only abuts but also partially overlaps L-shape region 328(3) of RP cell region 300(6).

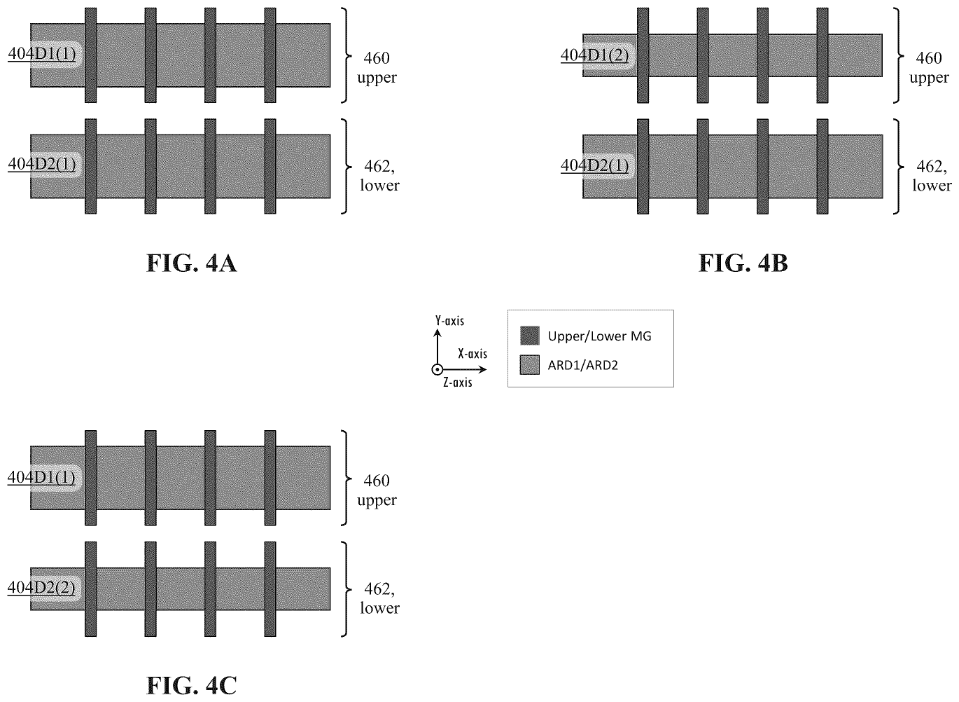

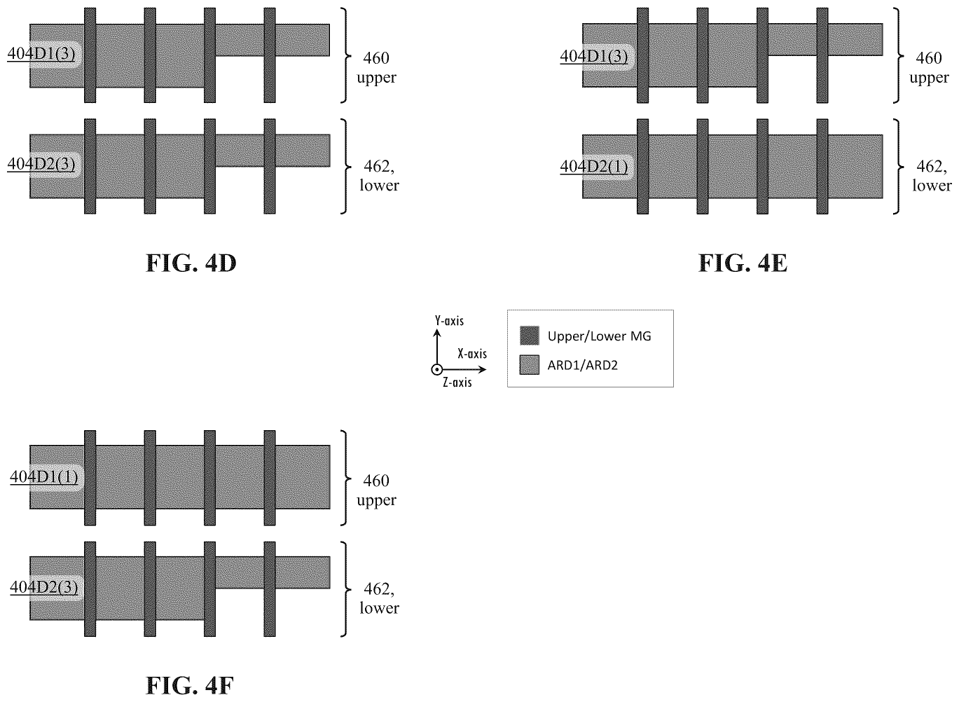

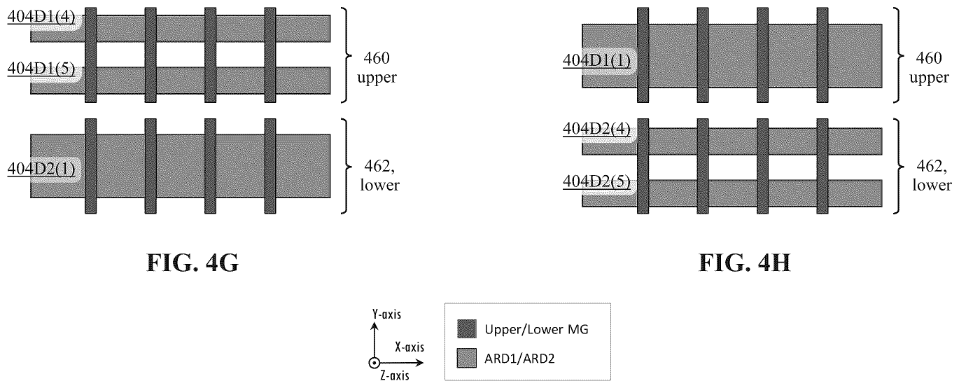

FIGS. 4A-4H are layout diagrams of corresponding arrangements of active regions, in accordance with some embodiments.

The layout diagrams of FIGS. 4A-4H (and in other layout diagrams disclosed herein) are representative of corresponding semiconductor devices. Structures in the semiconductor device are represented by patterns (also known as shapes) in the layout diagram. For simplicity of discussion, elements in the layout diagram of FIGS. 4A-4H (and also in other layout diagrams disclosed herein) will be referred to as if they are structures rather than patterns per se. For example, pattern 404D1(1) in FIG. 4A represents an active region having a first type of dopant, e.g., an N-type active region. In the following discussion, element 404D1(1) is referred to active region 404D1(1) rather than as active region pattern 404D1(1).

In FIGS. 4A-4H, as well as in other layout diagrams disclosed herein, an orthogonal Cartesian coordinate system is assumed in which a first direction is parallel to the X-axis, a second direction is parallel to the Y-axis and a third direction is parallel to the Z-axis. A layout diagram per se is a top view. Shapes in the layout diagram are two-dimensional relative to, e.g., the X-axis and the Y-axis, whereas the device being represented is three-dimensional. Relative to the Z-axis, upper division 460 is stacked on lower division 462.

Each of FIGS. 4A-4H represents a CFET stack that includes: one or more first active regions having a first type of dopant, e.g., an N-type dopant, in upper division 460; and one or more second active regions having a second type of dopant, e.g., a P-type dopant, in lower division 462. In some embodiments, the one or more lower active regions have the second type of dopant and the one or more upper active regions have the first type of dopant.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding semiconductor device are represented, i.e., selected layers of the layout diagram are omitted, e.g., for simplicity of illustration. FIGS. 4A-4H, as well as in other layout diagrams disclosed herein, are examples of layout diagrams in which selected layers have been omitted. Regarding FIGS. 4A-4H, show upper active regions, upper MG contacts, lower active regions and lower MG contacts, but omit other layers and structures for simplicity of illustration.

In FIGS. 4A-4H, a size of an active region relative to the Y-axis is referred to as a width of the active region. In FIG. 4A, upper active region 404D1(1) and lower active region 404D2(1) have substantially the same width. In FIG. 4B, the width of upper active region 404D1(2) is smaller than the width of lower active region 404D2(1). In FIG. 4C, the width of upper active region 404D1(1) is larger than the width of lower active region 404D2(2).

For a given CFET stack included in one or more of the present embodiments, together FIGS. 4A-4B show the width of an upper active region and the width of the lower active region can be the same or different, i.e., the widths are independent of each other.

In FIGS. 4D-4F, some of the active regions have a jog profile, namely upper active region 404D1(3) and lower active region 404D2(3). By contrast some of the active regions do not have a jog profile, namely active region 404D1(1) and 404D2(1). In some embodiments, an active region is described as having a jog profile when a size of the active region relative to a first axis (e.g., Y-axis) changes at different locations of the active region relative to a second axis (e.g., the X-axis). In some embodiments, an active region is described as having a jog profile when the width the active region changes at different locations along the X-axis. The jog profiles of upper active region 404D1(3) and lower active region 404D2(3) have an L-shape with a notch where the width changes. In some embodiments (not shown), a transition area of an active region having a jog profile, i.e., an area between corresponding MG contacts in which the width of the active region changes shape, has a shape substantially resembling a right trapezoid. In some embodiments (not shown), a transition area of an active region having a jog profile has a shape substantially resembling a type of trapezoid other than a right trapezoid.

In FIG. 4D, upper active region 404D1(1) and lower active region 404D2(1) have substantially the same jog profile. In FIG. 4E, upper active region 404D1(3) has a jog profile whereas lower active region 404D2(1). In FIG. 4F, upper active region 404D1(1) does not have a jog profile whereas lower active region 404D2(3) does have a jog profile.

For a given CFET stack included in one or more of the present embodiments, together FIGS. 4D-4E show the jog profile of an upper active region and the jog profile of the lower active region can be the same or different, i.e., the jog profiles are independent of each other.

In each of FIGS. 4G-4H, upper division 460 and lower division 462 have different numbers of active regions. In FIG. 4G, upper division 460 of the CFET stack includes two active regions, namely active regions 404D1(4) and 404D1(5). Lower division 462 of the CFET stack of FIG. 4G includes one active region, namely active region 404D2(1). The widths of active regions 404D1(4) and 404D1(5) are substantially the same and substantially smaller than the width of active region 404D2(1). In FIG. 4H, upper division 460 of the CFET stack includes one active region, namely active region 404D1(1). Lower division 462 of the CFET stack of FIG. 4H includes two active regions, namely active regions 404D2(4) and 404D2(5). The widths of active regions 404D2(4) and 404D2(5) are substantially the same and substantially smaller than the width of active region 404D2(1).

For a given CFET stack included in one or more of the present embodiments, together FIGS. 4G-4H show that a total number of upper active regions and at total number of lower active regions can be the same or different, i.e., the total numbers are independent of each other.

In some embodiments, active region 404D2(1) of FIG. 4G is the result of having merged active regions 404D2(4) and 404D2(5) of FIG. 4H. In some embodiments, active region 404D1(1) of FIG. 4H is the result of having merged active regions 404D1(4) and 404D1(5) of FIG. 4G.

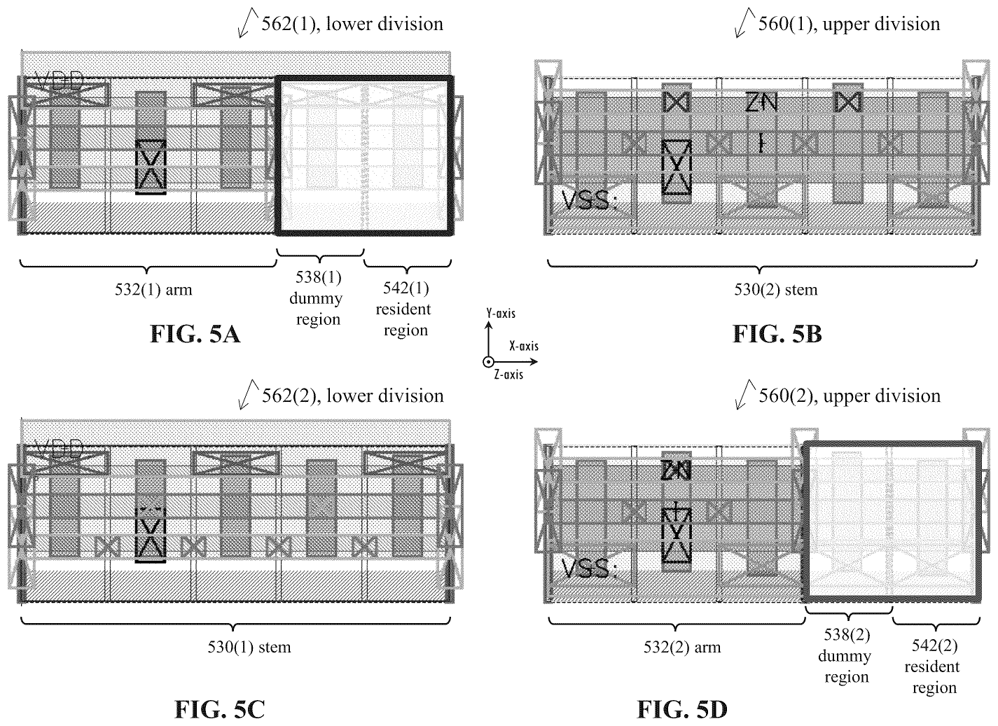

FIGS. 5A-5B are layout diagrams correspondingly of a lower division 562(1) and an upper division 560(2) of a CFET-based device, in accordance with some embodiments.

Together, lower division 562(1) and upper division 560(1) represent an inverter having a relative driving strength of D4, i.e., an INVD4 inverter. Together, lower division 562(1) and upper division 560(1) represent an RP cell that includes an L-shape region, a dummy region 538(1) and a resident region 542(1).

Lower division 562(1) includes an arm 532(1) of the L-shape region, dummy region 538(1) and a resident region 542(1).

Upper division 560(1) includes a stem 530(1) of the L-shape region.

FIGS. 5A-5B assume that lower division 562(1) is configured for PMOS technology and upper division 560(1) is configured for NMOS technology. In some embodiments, lower division 562(1) is configured for NMOS technology and upper division 560(1) is configured for PMOS technology.

FIGS. 5C-5D are layout diagrams correspondingly of a lower division 562(2) and an upper division 560(2) of a CFET-based device, in accordance with some embodiments.

Together, lower division 562(2) and upper division 560(2) represent an inverter having a relative driving strength of D4, i.e., an INVD4 inverter. Together, lower division 562(2) and upper division 560(2) represent an RP cell that includes an L-shape region, a dummy region 538(2) and a resident region 542(2).

Lower division 562(2) includes a stem 530(2) of the L-shape region.

Upper division 560(2) includes an arm 532(2) of the L-shape region, dummy region 538(2) and a resident region 542(2).

FIGS. 5C-5D assume that lower division 562(2) is configured for PMOS technology and upper division 560(2) is configured for NMOS technology. In some embodiments, lower division 562(2) is configured for NMOS technology and upper division 560(2) is configured for PMOS technology.

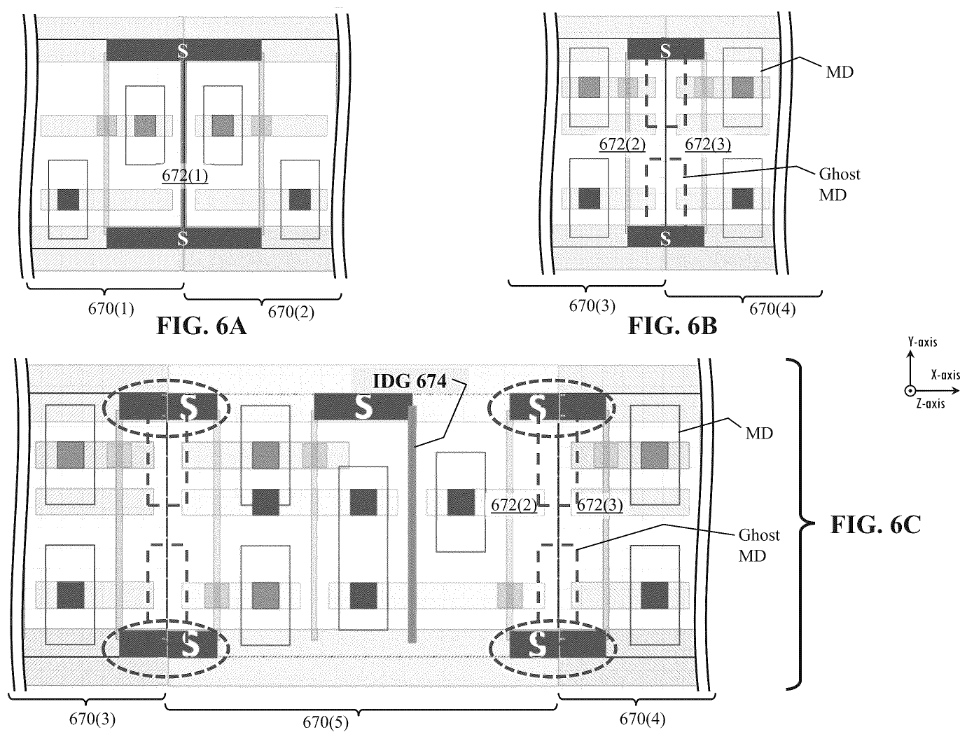

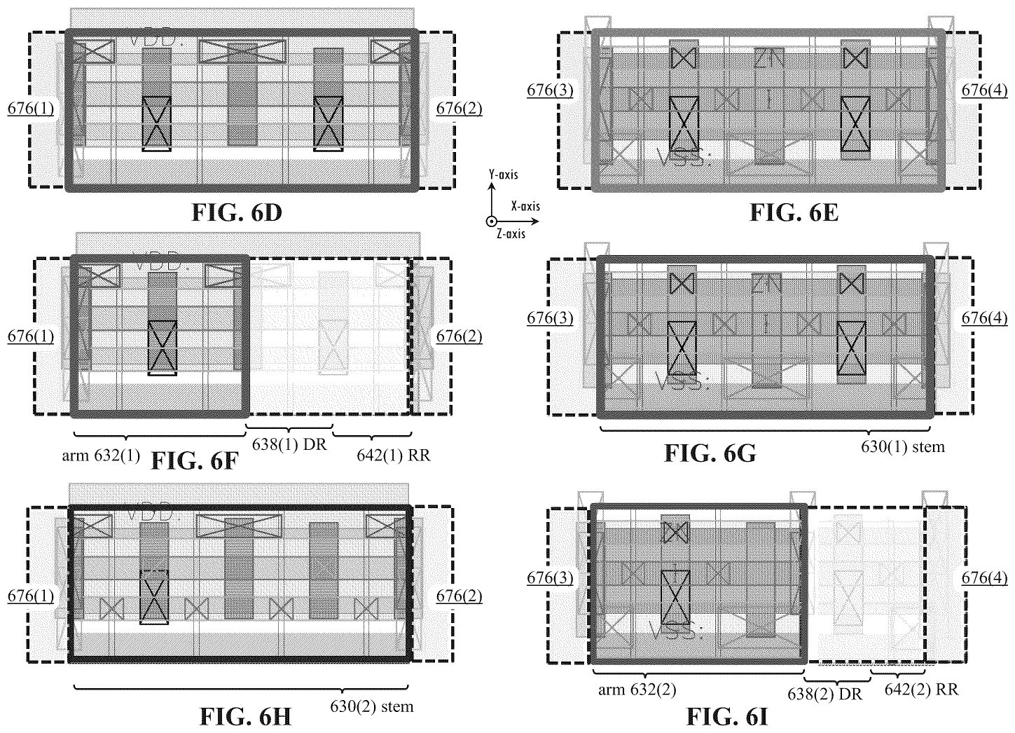

FIGS. 6A-6C are partial layout diagrams of cell regions, in accordance with some embodiments.

In the context of populating a layout diagram with standard cells, FIGS. 6A-6C show corresponding techniques for representing a border of a cell region that facilitate reducing a width of standard cells (relative to the X-axis) for purposes including placement of such standard cell regions into the layout diagram, thereby increasing densities of correspondingly resultant layout diagrams and devices manufactured based on such layout diagrams.

In FIG. 6A, relative to the X-axis, cell regions 670(1) and 670(2) are abutted. A gate structure 672(1) is shared by cell regions 670(1) and 670(2). Shared gate structure 672(1) represents a common boundary, i.e., the right and left boundaries correspondingly of cell regions 670(1) and 670(2). Relative to the X-axis, the use of shared gate structure 672(1) by cell regions 670(1) and 670(2) increases the density of a device which includes cell regions 670(1) and 670(2) as compared to counterpart abutting cell regions which do not share a gate structure on a common boundary.

In FIG. 6B, relative to the X-axis, cell regions 670(3) and 670(4) are abutted. A common boundary, i.e., the right and left boundaries correspondingly of cell regions 670(3) and 670(4), passes through areas (shown with phantom (dashed) lines in FIG. 6B) where MD contacts otherwise would have been formed. In some embodiments, an area where an MD contact otherwise would have been formed is referred to as a ghost MD.

The ghost MD contacts in FIG. 6B are shared by cell regions 670(3) and 670(4). The ghost MD contacts represent a common boundary, i.e., the right and left boundaries correspondingly of cell regions 670(3) and 670(4). Relative to the X-axis, the use of the shared ghost contacts by cell regions 670(3) and 670(4) increases the density of a device which includes cell regions 670(3) and 670(4) as compared to counterpart abutting cell regions which do not share ghost MD contacts on a common boundary.

FIG. 6C is similar to FIG. 6B except that FIG. 6B further includes a cell region 670(5). FIG. 6C represents a two-input AND gate having a relative driving strength of D1, i.e., an AN2D1 type of AND gate. Among other things, cell region 670(5) includes an IDG 674 in place of an active gate structure. Relative to the X-axis, cell region 6705(5) is between cell regions 670(3) and 670(4).

In FIG. 6C, relative to the X-axis, cell regions 670(3) and 670(5) are abutted. A common boundary, i.e., the right and left boundaries correspondingly of cell regions 670(3) and 670(5), passes through corresponding ghost MD contacts. Also, relative to the X-axis, cell regions 670(5) and 670(4) are abutted. A common boundary, i.e., the right and left boundaries correspondingly of cell regions 670(5) and 670(4), passes through corresponding ghost MD contacts.

FIGS. 6D, 6F and 6H are layout diagrams of a lower division of corresponding CFET-based devices, in accordance with some embodiments.

FIGS. 6E, 6G and 6I are layout diagrams of an upper division of corresponding CFET-based devices, in accordance with some embodiments.

FIGS. 6D-6H correspond to each other as follows: FIGS. 6D & 6E correspond; FIGS. 6F & 6G correspond; and FIGS. 6H & 6I correspond. Each of FIGS. 6D-6H is example of using left and/or right boundaries of a corresponding upper division or lower division of a CFET-based standard cell region which intersect corresponding ghost MD contacts (ghost-MD-based boundaries) thereby facilitating placement of such standard cell regions into the layout diagram, and thereby increasing densities of correspondingly resultant layout diagrams and devices manufactured based on such layout diagrams.

The pairings of FIGS. 6D & 6E, 6F & 6G and 6H & 6I represent an inverter having a relative driving strength of D4, i.e., an INVD4 inverter. Each of FIGS. 6D-6I includes area reductions, i.e., reductions in area, 676(1) and 676(2) on corresponding left and right sides resulting from using ghost-MD-based boundaries.

The pairings of FIGS. 6F & 6G and 6H & 6I represent corresponding RP cell regions, each of which includes an L-shape region, a dummy region (DR) and a resident region (RR).

FIGS. 6F and 6G are corresponding counterparts to FIGS. 5A-5B. The lower division of FIG. 6F includes an arm 632(1) of the L-shape region, a dummy region (DR) 638(1) and a resident region (RR) 642(1). The upper division of FIG. 6G includes a stem 630(1) of the L-shape region.

FIGS. 6F-6G assume that lower division is configured for PMOS technology and upper division is configured for NMOS technology. In some embodiments, lower division is configured for NMOS technology and upper division is configured for PMOS technology.

FIGS. 6H and 6I are corresponding counterparts to FIGS. 5C-5D. The lower division of FIG. 6H includes a stem 630(2) of the L-shape region. The upper division of FIG. 6I includes an arm 632(2) of the L-shape region, a dummy region (DR) 638(2) and a resident region (RR) 642(2).

FIGS. 6H-6I assume that lower division is configured for PMOS technology and upper division is configured for NMOS technology. In some embodiments, lower division is configured for NMOS technology and upper division is configured for PMOS technology.

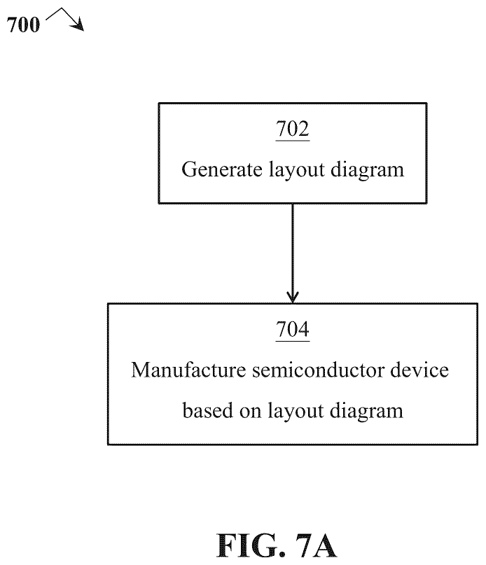

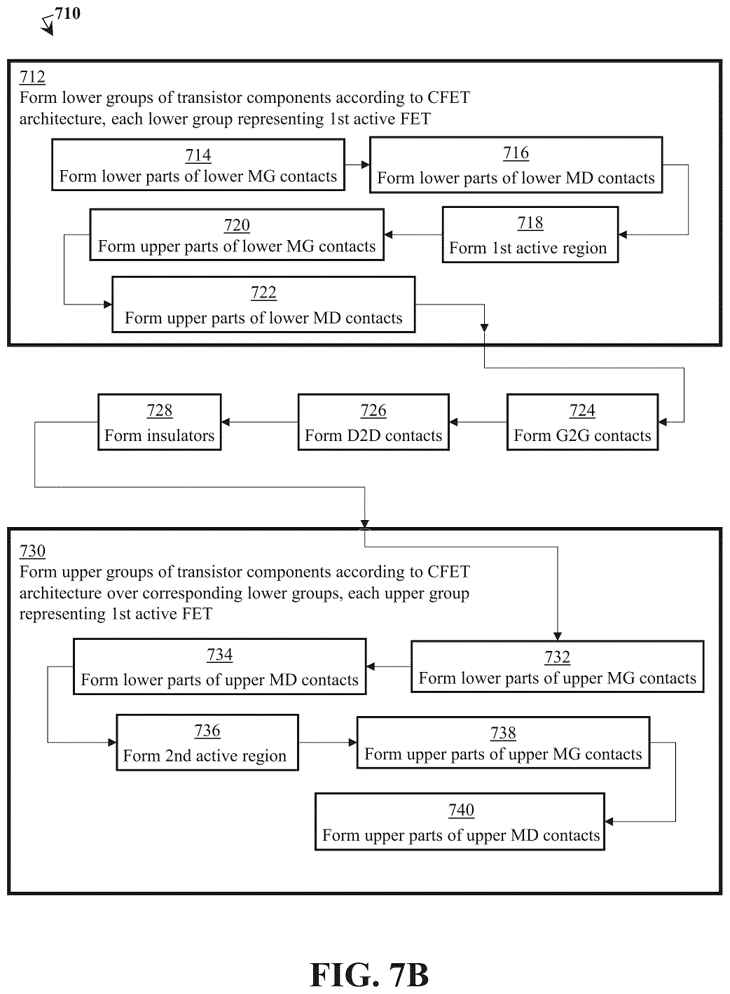

FIG. 7A is a flowchart 700 of a method of manufacturing a memory device, in accordance with some embodiments.

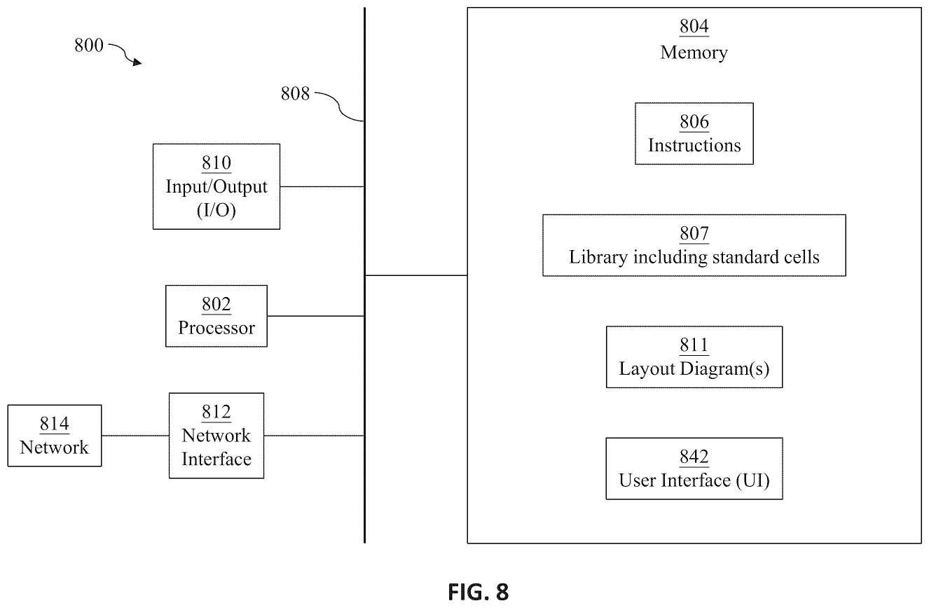

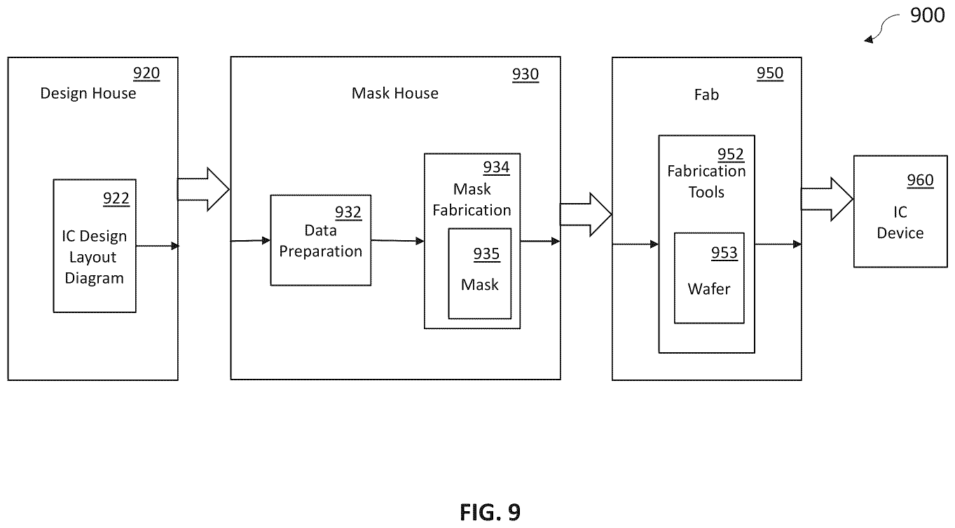

The method of flowchart (flow diagram) 700 is implementable, for example, using EDA system 800 (FIG. 8, discussed below) and an IC manufacturing system 900 (FIG. 9, discussed below), in accordance with some embodiments. Examples of a semiconductor device which can be manufactured according to the method of flowchart 700 include semiconductor devices based on the layout diagrams disclosed herein, or the like.

In FIG. 7, the method of flowchart 700 includes blocks 702-704. At block 702, a layout diagram is generated which, among other things, includes one or more of layout diagrams disclosed herein, or the like. Block 702 is implementable, for example, using EDA system 800 (FIG. 8, discussed below), in accordance with some embodiments.

In some embodiments, at block 702, a method of generating a layout diagram includes:
inspecting a first version of a layout diagram for RP cell regions according to the other approach, each of which includes an L-shape region and a dummy region but not a resident region; and
replacing one or more of the RP cell regions according to the other approach with RP cell regions each of which include the L-shape region, a resident region and a smaller dummy region. From block 702, flow proceeds to block 704.

At block 704, based on the layout diagram, at least one of (A) one or more photolithographic exposures are made or (b) one or more semiconductor masks are fabricated or (C) one or more components in a layer of a semiconductor device are fabricated. See discussion below of IC manufacturing system 900 in FIG. 9 below.

FIG. 7B is a flowchart 710 of a method of fabricating a semiconductor device, and more particularly a first rectangular parallelepiped (RP) cell region, in accordance with some embodiments.

Flowchart 710 is an example of block 704 of FIG. 7A. Flowchart 710 includes blocks 712-740. Examples provided in the context of the discussion of blocks 712-740 assume first, second and third orthogonal directions that are, e.g., correspondingly parallel to the X-axis, Z-axis and Y-axis. The method of flowchart 710 is implementable, for example, using IC manufacturing system 900 (FIG. 9, discussed below), in accordance with some embodiments. Examples of a semiconductor device which can be manufactured according to the method of flowchart 710 include semiconductor devices based on three-quarter perspective drawings, cross-sectional drawings and/or the layout diagrams of RP cell regions disclosed herein, or the like.

At block 712, lower groups of transistor components of the RP cell region are formed according to a complementary field-effect transistor (CFET) architecture. Examples of the first RP cell region include RP cell regions 200 of FIG. 2, 300(1) of FIGS. 3A-3B, or the like. An example of the lower group includes the lower group of FIG. 1, or the like. Each of the lower groups represents a corresponding active transistor configured with a first dopant-type, i.e., a corresponding first active transistor. An example of the first dopant type is P-type dopant, or the like. Examples of the first active transistors are PMOS transistors of FIGS. 1-2, or the like.

The lower groups of the RP cell region represent a stem of an L-shape region included in the RP cell region, the stem extending the first direction (e.g., parallel to the X-axis). Examples of the L-shape region include L-shape regions 228 of FIG. 2, 328(1) of FIGS. 3A-3B, or the like. Examples of the stem include stems 230 of FIG. 2, 330 of FIGS. 3A-3B, or the like. The stem includes first, second and third parts that correspondingly include one or more of the lower groups. Examples of the first part of the stem include first parts 234(1) of FIG. 2, 334(1) of FIGS. 3A-3B, or the like. Examples of the second part of the stem include second parts 234(2) of FIG. 2, 334(2) of FIGS. 3A-3B, or the like. Examples of the third part of the stem include third parts 234(3) of FIG. 2, 334(3) of FIGS. 3A-3B, or the like.

Block 712 of FIG. 7B includes blocks 714-722. At block 714, lower parts of lower metal-to-gate (MG) contacts are formed. Examples of the lower MG contacts include lower MG contact LMG of FIG. 1, lower MG contacts 212(1)-212(5) of FIG. 2, or the like. An example of the lower part of a lower MG contact is the lower part of lower MG contact LMG of FIG. 1, or the like. From block 714, flow proceeds to block 716.

At block 716, lower parts of lower metal-to-source/drain (MD) contacts are formed. Examples of the lower MD contacts include lower MD contacts LMD of FIG. 1, lower MD contacts 226(1)-226(6) of FIG. 2, or the like. An example of the lower part of a lower MD contact is the lower part of lower MD contacts LMD of FIG. 1, or the like. From block 716, flow proceeds to block 718.

At block 718, a first active region is formed, portions thereof being on corresponding portions of the lower parts of the lower MG contacts and the lower parts of the lower MD contacts. Examples of the first active region include active region ARD2 of FIG. 1, 204D2 of FIG. 2, or the like. From block 718, flow proceeds to block 720.

At block 720, upper parts of the lower MG contacts are formed on corresponding portions of the lower parts of the lower MG contacts and corresponding portions of the first active region. An example of the upper part of a lower MG contact is the upper part of the lower MG contact LMG of FIG. 1, or the like. From block 720, flow proceeds to block 722.

At block 722, upper parts of the lower MD contacts are formed on corresponding portions of the lower parts of the lower MD contacts and corresponding portions of the first active region. Examples of the upper part of a lower MG contact include the upper parts of the lower MD contacts LMD of FIG. 1, or the like. From block 722, flow exits block 714 and proceeds to block 724.

At block 724, MG-to-MG (G2G) contacts are formed on corresponding portions of the upper parts of the lower MG contacts. Examples of the G2G contacts include G2G contacts 211 of FIG. 2, or the like. In some embodiments, insulators (e.g., 206) are formed instead of one or more of the G2G contacts. From block 724, flow proceeds to block 726.

At block 726, MD-to-MD (D2D) contacts are formed on corresponding portions of the upper parts of the lower MD contacts. No D2D contacts are shown in FIG. 2. However, in some embodiments, one or more instances of an insulator (e.g., 206), otherwise formed on the upper parts of the lower MD contacts, are replaced with corresponding instances of D2D contacts. From block 726, flow proceeds to block 728.

At block 728, insulators are formed on corresponding portions of the upper parts of the lower MG contacts and/or on corresponding portions of the upper parts of the lower MD contacts. Examples of the insulators include the instances of insulator 206 on lower MG contacts 212(3)-212(5) of FIG. 2, the instances of insulator 206 on lower MD contacts 226(1)-226(6) of FIG. 2, or the like. In some embodiments, one or more instances of insulator 206 on corresponding lower MG contacts are replaced with instances of G2G contact 211. In some embodiments, one or more instances of insulator 206 on corresponding lower MD contacts are replaced with instances of a D2D contact (not shown). From block 728, flow proceeds to block 730.

At block 730, relative to the second direction (e.g., parallel to the Z-axis), upper groups of transistor components are formed according to the CFET architecture over corresponding ones of the lower groups of transistor components. An example of the upper group includes the upper group of FIG. 1, or the like.

A first set of the upper groups is over the first part (e.g., 334(1)) of the stem (330) and represents an arm of the L-shape region. Examples of the arm include arms 232 of L-shape region 228 of FIG. 2, 332 of L-shape region 328(1) of FIGS. 3A-3B, or the like. The arm extends in the second direction (e.g., parallel to the Z-axis) from the first part (e.g., 334(1)) of the stem (e.g., 330) to form a first notch. An example of the first notch is first notch 336 of FIG. 336 of FIGS. 3A-3B, or the like.

A second set of the upper groups is over the second part (e.g., 334(2)) of the stem (e.g., 330) and represents a dummy region included in the RP cell region (e.g., 302(1)). Examples of the dummy region include dummy regions 238 of FIG. 2, 338(1) of FIGS. 3A-3B, or the like. A third set of the upper groups is over the third part (e.g., 334(3)) of the stem (e.g., 330) and represents a resident region. Examples of the resident region include resident regions 242 of FIG. 1, 342(1) of FIGS. 3A-3B, or the like. The dummy region and the resident region are in the first notch (e.g., 336).

Each upper group of the arm (e.g., 332) and the resident region (e.g., 342(1) represents a corresponding active transistor configured with a second dopant-type, i.e., a second active transistor. An example of the second dopant type is N-type dopant, or the like. Examples of the second active transistors are NMOS transistors of FIGS. 1-2, or the like. Each upper group of the dummy region (e.g., 338(1) represents a corresponding dummy transistor.

The lower groups and upper groups of the L-shape region (e.g., 228, 328(1)) have corresponding operabilities which comprise a function of the L-shape region that represents a function of the RP cell region (e.g., 202, 302(1)). The upper groups of the resident region (e.g., 342(1) have corresponding operabilities which are free from comprising the function of the L-shape region (e.g., 328(1)).

Block 730 includes blocks 732-740. At block 732, lower parts of upper MG contacts are formed over corresponding ones of the upper parts of the lower MG contacts (e.g., 212(1)-212(3)) and on corresponding ones of the G2G contacts (e.g., 211) or the insulator (e.g., 206). Examples of the upper MG contacts include upper MG contact UMG of FIG. 1, upper MG contacts 210(1)-210(3) of FIG. 2, or the like. An example of the lower part of a upper MG contact is the lower part of upper MG contact LMG of FIG. 1, or the like. From block 730, flow proceeds to block 732.

At block 734, lower parts of upper MD contacts are formed over corresponding ones of the upper parts of the lower MD contacts (e.g., 226(x)) and on corresponding ones of the insulator (e.g., 206) or the D2D contacts (the latter not being shown). Examples of the upper MD contacts include upper MD contacts UMD of FIG. 1, upper MD contacts 224(1)-224(6) of FIG. 2, or the like. An example of the lower part of a upper MD contact is the lower part of upper MD contacts UMD of FIG. 1, or the like. From block 734, flow proceeds to block 736.

At block 736, a second active region is formed, portions thereof being on corresponding portions of the lower parts of the upper MG contacts and the lower parts of the upper MD contacts. Examples of the second active region include active region ARD1 of FIG. 1, 204D1 of FIG. 2, or the like. From block 736, flow proceeds to block 738.

At block 738, upper parts of the upper MG contacts are formed on corresponding portions of the lower parts of the upper MG contacts and corresponding portions of the second active region. An example of the upper part of a upper MG contact is the upper part of the upper MG contact UMG of FIG. 1, or the like. From block 738, flow proceeds to block 740.

At block 740, upper parts of the upper MD contacts are formed on corresponding portions of the lower parts of the upper MD contacts and corresponding portions of the second active region. Examples of the upper part of a upper MG contact include the upper parts of the upper MD contacts UMD of FIG. 1, or the like. From block 740, flow exits block 730.

In some embodiments, regarding the dummy region (e.g., 338(1)), block 730 includes the following. Lower parts of upper dummy MG (DG) contacts are formed, e.g., before forming the second active region at block 736. Upper parts of the upper DG contacts are formed, e.g., before the upper parts of the upper MD contacts are formed at block 740. The lower parts of upper dummy MG (DG) contacts are formed over corresponding ones of the upper parts of the lower MG contacts and on corresponding ones of insulator (e.g., 206), the latter being on upper parts of corresponding lower MG contacts (e.g., 212(3)-212(4). Examples of the upper DG contacts include upper DG contacts 214(1)-214(2) of FIG. 2, or the like. The upper parts of the upper DG contacts are formed on corresponding portions of the lower parts of the upper DG contacts (214(1)-214(2)) and corresponding portions of the second active region (e.g., 204D1).

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion or all of, e.g., the method of FIG. 5 (block 502), methods of generating layout diagrams such as FIGS. 2B-2R, methods of generating layout diagrams corresponding to block diagrams such as FIGS. 1A-1H, or the like, in accordance with one or more embodiments (hereinafter, the noted processes and/or methods). Storage medium 804, amongst other things, stores layout diagrams 811 such as the layout diagrams disclosed herein, other the like.

Processor 802 is electrically coupled to computer-readable storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause system 800 to be usable for performing a portion or all of the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, storage medium 804 stores computer program code 806 configured to cause system 800 (where such execution represents (at least in part) the EDA tool) to be usable for performing a portion or all of the noted processes and/or methods. In one or more embodiments, storage medium 804 further stores information which facilitates performing a portion or all of the noted processes and/or methods. In one or more embodiments, storage medium 804 stores library 807 of standard cells including such standard cells as disclosed herein. In some embodiments, storage medium 804 stores one or more layout diagrams 811.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 800.

System 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

Based on the layout diagram generated by block 502 of FIG. 5, the IC manufacturing system 900 implements block 504 of FIG. 5 wherein at least one of (A) one or more semiconductor masks or (B) at least one component in a layer of an inchoate semiconductor integrated circuit is fabricated using manufacturing system 900.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are be repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a device includes: a first rectangular parallelepiped (RP) cell region including a three-dimensional (3D) L-shape region, a dummy region and a resident region; the L-shape region including active transistors having corresponding operabilities which comprise a function of the L-shape region that represents a function of the RP cell region; the resident region including one or more active transistors having corresponding operabilities which are free from comprising the function of the L-shape region; the L-shape region including a stem including first, second and third parts, and an arm extending from the first part of the stem to form a first notch, and the dummy region and the resident region being in the first notch; and first type active transistors (first active transistors) of the arm being stacked correspondingly with respect to one or more second type active transistors (second active transistors) of the first part of the stem; one or more dummy transistors of the dummy region being stacked correspondingly with respect to one or more of the second active transistors of the second part of the stem; and one or more first active transistors of the resident region being stacked correspondingly with respect to one or more second active transistors of the third part of the stem.

In some embodiments, the dummy region is between the resident region and the arm.

In some embodiments, the first RP cell region includes a second RP cell region; and the second RP cell region is abutted to each of arm, stem, dummy region and resident region.

In some embodiments, the first RP cell region includes: a first active region extends through each of the arm and the notch; and a second active region extends through the stem; and the first active region and the second active region have substantially a same width.

In some embodiments, the first RP cell region includes: a first active region extends through each of the arm and the notch; and a second active region extends through the stem; and the first active region and the second active region have substantially different widths.

In some embodiments, the first RP cell region includes: a first active region extends through each of the arm and the notch; and a second active region extends through the stem; and the first active region and the second active region have corresponding first and second jog-profiles.

In some embodiments, the first jog-profile of the first active region and the second jog-profile of the second active region are substantially different.

In some embodiments, the first jog-profile of the first active region and the second jog-profile of the second active region are substantially same.

In some embodiments, the first RP cell region includes: one or more first active regions extending through each of the arm and the notch; and one or more second active regions extending through the stem; and a first total number of the one or more first active regions and a second total number of the one or more second active regions are different.

In some embodiments, the first RP cell region includes: one or more first active regions extending through each of the arm and the notch; and one or more second active regions extending through the stem; and a first total number of the one or more first active regions and a second total number of the one or more second active regions are same.

In some embodiments, a device includes: first and second rectangular parallelepiped (RP) cell regions correspondingly including three-dimensional (3D) first and second L-shape regions, first and second dummy regions and first and second resident regions; each of the first and second L-shape regions including active transistors having corresponding operabilities which comprise a function correspondingly of the first and second L-shape regions that represents a function correspondingly of the first and second RP cell regions; each of the first and second resident regions including one or more active transistors having corresponding operabilities which are free from comprising the function of the L-shape region correspondingly of the first and second RP cell regions; each of the first and second L-shape regions including a stem including first, second and third parts, and an arm extending from the first part of the corresponding stem to form a first notch; the first and second dummy regions representing the third parts correspondingly of the second and first RP cell regions; for each of the first and second RP cell regions, the dummy region and the resident region being in the first notch; and first type active transistors (first active transistors) of each arm being stacked correspondingly with respect to one or more second type active transistors (second active transistors) of the first part of the corresponding stem; one or more dummy transistors of each dummy region being stacked correspondingly with respect to one or more of the second active transistors of the second part of the corresponding stem; and first and second RP cell regions being complementarily oriented relative to each other such that one or more first active transistors of each resident region being stacked correspondingly with respect to one or more active transistors of the third part of the corresponding stem.

In some embodiments, the stem extends in a first direction; the arm extends from the first part of the corresponding stem in a second direction perpendicular to the first direction; relative to each of the first direction and a third direction perpendicular to each of the first and second directions, the second RP cell region is rotated 180 degrees relative to the first RP cell region.

In some embodiments, the stem extends in a first direction; the arm extends from the first part of the corresponding stem in a second direction perpendicular to the first direction; relative to each of the second direction, the second RP cell region is rotated 90 degrees relative to the first RP cell region.

In some embodiments, relative to each of the first direction, an intermediary RP cell region is rotated 180 degrees relative to the first RP cell region; and relative to plane formed by the first direction and a third direction perpendicular to each of the first and second directions, the second RP cell region is mirror-symmetric with respect to the intermediary RP cell region.

In some embodiments, the first RP cell region further includes a first RP internal region abutted to the corresponding L-shape region; or the second RP cell region further includes a second RP internal region abutted to the corresponding L-shape region.

In some embodiments, each of the first and second RP cell regions includes: a first active region extends through each of the arm and the notch; and a second active region extends through the stem; and for at least one of the first and second RP cell regions, and relative to a third direction perpendicular to each of the first and second directions, the first active region and the second active region have substantially a same width.

In some embodiments, each of the first and second RP cell regions includes: a first active region extends through each of the arm and the notch; and a second active region extends through the stem; and for at least one of the first and second RP cell regions, and relative to a third direction perpendicular to each of the first and second directions, the first active region and the second active region have substantially different widths.

In some embodiments, each of the first and second RP cell regions includes: a first active region extends through each of the arm and the notch; and a second active region extends through the stem; and for at least one of the first and second RP cell regions, and relative to a third direction perpendicular to each of the first and second directions, the first active region and the second active region have corresponding first and second jog-profiles.

In some embodiments, for at least one of the first and second RP cell regions, and the first jog-profile of the first active region and the second jog-profile of the second active region are substantially same.

In some embodiments, for at least one the first jog-profile of the first active region and the second jog-profile of the second active region are substantially different.

In some embodiments, each of the first and second RP cell regions includes: one or more first active regions extending through each of the arm and the notch; and one or more second active regions extending through the stem; and for at least one of the first RP cell region or the second RP cell region, a first total number of the one or more first active regions and a second total number of the one or more second active regions are same.

In some embodiments, each of the first and second RP cell regions includes: one or more first active regions extending through each of the arm and the notch; and one or more second active regions extending through the stem; and for at least one of the first RP cell region or the second RP cell region, a first total number of the one or more first active regions and a second total number of the one or more second active regions are different.

In some embodiments, a method (forming a semiconductor device) includes forming a first rectangular parallelepiped (RP) cell region including: forming lower groups of transistor components, each of the lower groups representing a corresponding first type of active transistor, the lower groups representing a stem of an L-shape region included in the RP cell region, and the stem including first, second and third parts that correspondingly include one or more of the lower groups; and forming upper groups of transistor components over corresponding ones of the lower groups, a first set of the upper groups being over the first part of the stem and representing an arm of the L-shape region, the arm extending from the first part of the stem to form a first notch, a second set of the upper groups being over the second part of the stem and representing a dummy region included in the RP cell region, a third set of the upper groups being over the third part of the stem and representing a resident region, the dummy region and the resident region being in the first notch; each upper group of the arm and the resident region representing a corresponding second type of active transistor, and each upper group of the dummy region representing a corresponding dummy transistor; the lower groups and upper groups of the L-shape region having corresponding operabilities which comprise a function of the L-shape region that represents a function of the RP cell region; and the upper groups of the resident region having corresponding operabilities which are free from comprising the function of the L-shape region.

In some embodiments, the forming lower groups of transistor components includes: forming lower parts of lower metal-to-gate (MG) contacts; forming lower parts of lower metal-to-source/drain (MD) contacts; forming a first active region, portions thereof being on corresponding portions of the lower parts of the lower MG contacts and the lower parts of the lower MD contacts; forming upper parts of the lower MG contacts on corresponding portions of the lower parts of the lower MG contacts and corresponding portions of the first active region; and forming upper parts of the lower MD contacts on corresponding portions of the lower parts of the lower MD contacts and corresponding portions of the first active region.

In some embodiments, for each of the arm and the resident region, the forming upper groups of transistor components includes: forming lower parts of upper MG contacts over corresponding ones of the upper parts of the lower MG contacts; forming lower parts of upper MD contacts over corresponding ones of the upper parts of the lower MD contacts; forming a second active region over the first active region, portions of the second active region being on corresponding portions of the lower parts of the upper MG contacts and the lower parts of the upper MD contacts; forming upper parts of the upper MG contacts on corresponding portions of the lower parts of the upper MG contacts and corresponding portions of the second active region; and forming upper parts of the upper MD contacts on corresponding portions of the lower parts of the upper MD contacts and corresponding portions of the second active region.

In some embodiments, before the forming upper groups of transistor components, the method further includes: forming insulators on corresponding portions of the upper parts of the lower MG contacts; and the forming lower parts of upper MG contacts forms the lower parts of the upper MG contacts on corresponding ones of the insulators.

In some embodiments, before the forming upper groups of transistor components, the method further includes: forming MG-to-MG (G2G) contacts on corresponding portions of the upper parts of the lower MG contacts; and the forming lower parts of upper MG contacts forms the lower parts of the upper MG contacts on corresponding ones of the G2G contacts.

In some embodiments, before the forming upper groups of transistor components, the method further includes: forming insulators on corresponding portions of the upper parts of the lower MD contacts; and the forming lower parts of upper MD contacts forms the lower parts of the upper MD contacts on corresponding ones of the insulators.

In some embodiments, before the forming upper groups of transistor components, the method further includes: forming MD-to-MD (D2D) contacts on corresponding portions of the upper parts of the lower MD contacts; and the forming lower parts of upper MD contacts forms the lower parts of the upper MD contacts on corresponding ones of the D2D contacts.

In some embodiments, for the dummy region, the forming upper groups of transistor components includes: forming lower parts of upper dummy MG (DG) contacts over corresponding ones of the upper parts of the lower MG contacts; forming lower parts of upper MD contacts over corresponding ones of the upper parts of the lower MD contacts; forming a second active region over the first active region, portions of the second active region being on corresponding portions of the lower parts of upper DG contacts and the lower parts of the upper MD contacts; forming upper parts of the upper DG contacts on corresponding portions of the lower parts of upper DG contacts and corresponding portions of the second active region; and forming upper parts of the upper MD contacts on corresponding portions of the lower parts of the upper MD contacts and corresponding portions of the second active region.

In some embodiments, before the forming upper groups of transistor components, the method further includes: forming insulators on corresponding portions of the upper parts of the lower MG contacts; and the forming lower parts of dummy MG contacts forms the lower parts of dummy MG contacts on corresponding ones of the insulators.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A device comprising:
a first rectangular parallelepiped (RP) cell region including a three-dimensional (3D) L-shape region, a dummy region and a resident region;
the L-shape region including active transistors having corresponding operabilities which comprise a function of the L-shape region that represents a function of the RP cell region;
the resident region including one or more active transistors having corresponding operabilities which are free from comprising the function of the L-shape region;
the L-shape region including
a stem including first, second and third parts, and
an arm extending from the first part of the stem to form a first notch, and
the dummy region and the resident region being in the first notch; and
first type active transistors (first active transistors) of the arm being stacked correspondingly with respect to one or more second type active transistors (second active transistors) of the first part of the stem;
one or more dummy transistors of the dummy region being stacked correspondingly with respect to one or more of the second active transistors of the second part of the stem; and
one or more first active transistors of the resident region being stacked correspondingly with respect to one or more second active transistors of the third part of the stem.

2. The device of claim 1, wherein:
the dummy region is between the resident region and the arm.

3. The device of claim 1, wherein:
the first RP cell region includes a second RP cell region; and
the second RP cell region is abutted to each of arm, stem, dummy region and resident region.

4. The device of claim 1, wherein:
the first RP cell region includes:
a first active region extends through each of the arm and the notch; and
a second active region extends through the stem; and
the first active region and the second active region have substantially a same width.

5. The device of claim 1, wherein:
the first RP cell region includes:
a first active region extends through each of the arm and the notch; and
a second active region extends through the stem; and
the first active region and the second active region have substantially different widths.

6. The device of claim 1, wherein:
the first RP cell region includes:
a first active region extends through each of the arm and the notch; and
a second active region extends through the stem; and
the first active region and the second active region have corresponding first and second jog-profiles.

7. The device of claim 6, wherein:
the first jog-profile of the first active region and the second jog-profile of the second active region are substantially different.

8. The device of claim 1, wherein:
the first RP cell region includes:
one or more first active regions extending through each of the arm and the notch; and
one or more second active regions extending through the stem; and
a first total number of the one or more first active regions and a second total number of the one or more second active regions are different.

9. A device comprising:
first and second rectangular parallelepiped (RP) cell regions correspondingly including three-dimensional (3D) first and second L-shape regions, first and second dummy regions and first and second resident regions;
each of the first and second L-shape regions including active transistors having corresponding operabilities which comprise a function correspondingly of the first and second L-shape regions that represents a function correspondingly of the first and second RP cell regions;
each of the first and second resident regions including one or more active transistors having corresponding operabilities which are free from comprising the function of the L-shape region correspondingly of the first and second RP cell regions;
each of the first and second L-shape regions including
a stem including first, second and third parts, and
an arm extending from the first part of the corresponding stem to form a first notch;
the first and second dummy regions representing the third parts correspondingly of the second and first RP cell regions;
for each of the first and second RP cell regions, the dummy region and the resident region being in the first notch; and
first type active transistors (first active transistors) of each arm being stacked correspondingly with respect to one or more second type active transistors (second active transistors) of the first part of the corresponding stem;
one or more dummy transistors of each dummy region being stacked correspondingly with respect to one or more of the second active transistors of the second part of the corresponding stem; and
first and second RP cell regions being complementarily oriented relative to each other such that one or more first active transistors of each resident region being stacked correspondingly with respect to one or more active transistors of the third part of the corresponding stem.

10. The device of claim 9, wherein:
the stem extends in a first direction;
the arm extends from the first part of the corresponding stem in a second direction perpendicular to the first direction;
relative to each of the first direction and a third direction perpendicular to each of the first and second directions, the second RP cell region is rotated 180 degrees relative to the first RP cell region.

11. The device of claim 10, wherein:
relative to each of the second direction, the second RP cell region is rotated 90 degrees relative to the first RP cell region.

12. The device of claim 9, wherein:
the stem extends in a first direction;
the arm extends from the first part of the corresponding stem in a second direction perpendicular to the first direction;
relative to each of the first direction, an intermediary RP cell region is rotated 180 degrees relative to the first RP cell region; and
relative to a plane formed by the first direction and a third direction perpendicular to each of the first and second directions, the second RP cell region is mirror-symmetric with respect to the intermediary RP cell region.

13. A method of forming a semiconductor device, the method comprising forming a first rectangular parallelepiped (RP) cell region including:
forming lower groups of transistor components, each of the lower groups representing a corresponding first type of active transistor,
the lower groups representing a stem of an L-shape region included in the RP cell region, and
the stem including first, second and third parts that correspondingly include one or more of the lower groups; and
forming upper groups of transistor components over corresponding ones of the lower groups,
a first set of the upper groups being over the first part of the stem and representing an arm of the L-shape region,
the arm extending from the first part of the stem to form a first notch,
a second set of the upper groups being over the second part of the stem and representing a dummy region included in the RP cell region,
a third set of the upper groups being over the third part of the stem and representing a resident region,
the dummy region and the resident region being in the first notch;
each upper group of the arm and the resident region representing a corresponding second type of active transistor, and
each upper group of the dummy region representing a corresponding dummy transistor;
the lower groups and upper groups of the L-shape region having corresponding operabilities which comprise a function of the L-shape region that represents a function of the RP cell region; and
the upper groups of the resident region having corresponding operabilities which are free from comprising the function of the L-shape region.

14. The method of claim 13, wherein the forming lower groups of transistor components includes:
forming lower parts of lower metal-to-gate (MG) contacts;
forming lower parts of lower metal-to-source/drain (MD) contacts;
forming a first active region, portions thereof being on corresponding portions of the lower parts of the lower MG contacts and the lower parts of the lower MD contacts;
forming upper parts of the lower MG contacts on corresponding portions of the lower parts of the lower MG contacts and corresponding portions of the first active region; and
forming upper parts of the lower MD contacts on corresponding portions of the lower parts of the lower MD contacts and corresponding portions of the first active region.

15. The method of claim 14, wherein, for each of the arm and the resident region, the forming upper groups of transistor components includes:
forming lower parts of upper MG contacts over corresponding ones of the upper parts of the lower MG contacts;
forming lower parts of upper MD contacts over corresponding ones of the upper parts of the lower MD contacts;
forming a second active region over the first active region, portions of the second active region being on corresponding portions of the lower parts of the upper MG contacts and the lower parts of the upper MD contacts;
forming upper parts of the upper MG contacts on corresponding portions of the lower parts of the upper MG contacts and corresponding portions of the second active region; and
forming upper parts of the upper MD contacts on corresponding portions of the lower parts of the upper MD contacts and corresponding portions of the second active region.

16. The method of claim 15, wherein:
before the forming upper groups of transistor components, the method further comprises:
forming insulators on corresponding portions of the upper parts of the lower MG contacts; and
the forming lower parts of upper MG contacts forms the lower parts of the upper MG contacts on corresponding ones of the insulators.

17. The method of claim 15, wherein:
before the forming upper groups of transistor components, the method further comprises:
forming MG-to-MG (G2G) contacts on corresponding portions of the upper parts of the lower MG contacts; and
the forming lower parts of upper MG contacts forms the lower parts of the upper MG contacts on corresponding ones of the G2G contacts.

18. The method of claim 15, wherein:
before the forming upper groups of transistor components, the method further comprises:
forming insulators on corresponding portions of the upper parts of the lower MD contacts; and
the forming lower parts of upper MD contacts forms the lower parts of the upper MD contacts on corresponding ones of the insulators.

19. The method of claim 15, wherein:
before the forming upper groups of transistor components, the method further comprises:
forming MD-to-MD (D2D) contacts on corresponding portions of the upper parts of the lower MD contacts; and
the forming lower parts of upper MD contacts forms the lower parts of the upper MD contacts on corresponding ones of the D2D contacts.

20. The method of claim 14, wherein, for the dummy region, the forming upper groups of transistor components includes:
forming lower parts of upper dummy MG (DG) contacts over corresponding ones of the upper parts of the lower MG contacts;
forming lower parts of upper MD contacts over corresponding ones of the upper parts of the lower MD contacts;
forming a second active region over the first active region, portions of the second active region being on corresponding portions of the lower parts of upper DG contacts and the lower parts of the upper MD contacts;
forming upper parts of the upper DG contacts on corresponding portions of the lower parts of upper DG contacts and corresponding portions of the second active region; and
forming upper parts of the upper MD contacts on corresponding portions of the lower parts of the upper MD contacts and corresponding portions of the second active region.
